(19) United States
(12) Patent Application Publication
(10) Pub. No.: US 2018/0167744 A1
(43) Pub. Date: Jun. 14, 2018

(54) TRANSDUCER PACKAGING

(71) Applicant: CIRRUS LOGIC INTERNATIONAL SEMICONDUCTOR LTD., Edinburgh (GB)

(72) Inventors: Marek Sebastian Piechocinski, Edinburgh (GB); Roberto Brioschi, Austin, TX (US); Rkia Achehboune, Edinburgh (GB); Aleksey Sergeyevich Khenkin, Nashua, NH (US)

(73) Assignee: CIRRUS LOGIC INTERNATIONAL SEMICONDUCTOR LTD., Edinburgh (GB)

(21) Appl. No.: 15/832,186

(22) Filed: Dec. 5, 2017

Related U.S. Application Data
(60) Provisional application No. 62/433,081, filed on Dec. 12, 2016.

(30) Foreign Application Priority Data
Oct. 16, 2017 (GB) 1716953.3

(51) Int. Cl. H04R 19/04; B81B 7/00; B81C 1/00; H04R 19/00; H04R 31/00

(52) U.S. Cl. CPC H04R 19/04; B81B 7/0061; B81C 1/00309; H04R 19/005; H04R 2410/03; B81B 2201/0257; H04R 2201/003; H04R 2499/11; H04R 31/00

(57) ABSTRACT

The application describes a lid for a transducer package, wherein an interior surface of the lid is provided with a plurality of dimples. The dimples are provided in a ceiling surface of the lid or in a side-wall surface of the lid. The dimples may be arranged to form a regular array. The dimples serve to create a turbulent boundary layer to decouple the interior surface of lid from airflow arising inside the package chamber, thus alleviating noise.

### FIELD

The field of representative embodiments of this disclosure relates to packaging for a MEMS transducer, such as a MEMS microphone. In particular the present application relates to a lid for a transducer package.

### BACKGROUND

Consumer electronics devices are continually getting smaller and, with advances in technology, are gaining ever-increasing performance and functionality. This is clearly evident in the technology used in consumer electronic products and especially, but not exclusively, portable products such as mobile phones, audio players, video players, personal digital assistants (PDAs), various wearable devices, mobile computing platforms such as laptop computers or tablets and/or games devices. Requirements of the mobile phone industry for example, are driving the components to become smaller with higher functionality and reduced cost. It is therefore desirable to integrate functions of electronic circuits together and combine them with transducer devices such as microphones and speakers.

Micro-electromechanical-system (MEMS) transducers, such as MEMS microphones are therefore finding application in many of these devices.

Microphone devices formed using MEMS fabrication processes typically comprise one or more membranes with electrodes for read-out/drive that are deposited on or within the membranes and/or a substrate or back-plate. In the case of MEMS pressure sensors and microphones, the electrical output signal read-out is usually accomplished by measuring a signal related to the capacitance between the electrodes.

To provide protection the MEMS transducer will be contained within a package. The package effectively encloses the MEMS transducer and can provide environmental protection and may also provide shielding for electromagnetic interference (EMI) or the like. The package also provides at least one external connection for outputting the electrical signal to downstream circuitry. For microphones and the like the package will typically have a sound port to allow transmission of sound waves to/from the transducer within the package and the transducer may be configured so that the flexible membrane is located between first and second volumes, i.e. spaces/cavities that may be filled with air (or some other gas suitable for transmission of acoustic waves), and which are sized sufficiently so that the transducer provides the desired acoustic response. The sound port acoustically couples to a first volume on one side of the transducer membrane, which may sometimes be referred to as a front volume. The second volume, sometimes referred to as a back volume, on the other side of the one of more membranes is generally required to allow the membrane to move freely in response to incident sound or pressure waves, and this back volume may be substantially sealed (although it will be appreciated by one skilled in the art that for MEMS microphones and the like the first and second volumes may be connected by one or more flow paths, such as small holes in the membrane, that are configured so as present a relatively high acoustic impedance at the desired acoustic frequencies but which allow for low-frequency pressure equalisation between the two volumes to account for pressure differentials due to temperature changes or the like).

Various package designs are known. For example, FIGS. 1 illustrates a “lid-type” package 100. A MEMS transducer 101 is mounted to an upper surface of a package substrate 102. The package substrate 102 may be PCB (printed circuit board) or any other suitable material. A cover or “lid” 103 is located over the transducer 101 and is attached to the upper surface of the package substrate 102 to define a chamber having an interior surface. The cover 103 may be a metallic lid. An aperture 104 in the substrate 102 provides a sound port and allows acoustic signals to enter the package. Alternatively or additionally, a sound port may be provided by means of an aperture formed in the lid. In the FIG. 1 illustration, the MEMS transducer is mounted such that the flexible membrane of the transducer extends over the sound port. The package may also comprise an integrated circuit 105. The integrated circuit will typically be formed on a die of semiconductor material and will be customised for a particular application. The integrated circuit will be electrically connected to electrodes of the transducer 101 and an electrically conductive path will be provided between the integrated circuit and an electrical connection provided on an external surface of the package. The integrated circuit may provide bias to the transducer and may buffer or amplify a signal from the transducer. The transducer may be co-integrated with the integrated circuitry.

Pressure waves incident on a transducer package cause air to move in and out of the package via the sound port. Thus, it will be appreciated that air flow arises within the transducer package and that air molecules will therefore interact with the interior surface of the chamber. In particular, the air molecules that encounter one of the inner surfaces of the chamber will tend to drag on the inner surface giving rise to acoustic noise that is detectable by the sensor of the microphone transducer. As the package volume is reduced the number of air molecules interacting with the lid internal surface increases—relative to the number of air molecules in the entire volume. Hence, the effect of surface drag may be more pronounced in smaller package geometries. Thus, this problem becomes more apparent as the package size is reduced due to the potential deterioration in the noise performance of the microphone transducer. Thus, the drive to miniaturise MEMS transducers further exacerbates the problem of acoustic noise arising within MEMS transducer packages, in particular packages intended for MEMS microphone transducers.

### SUMMARY

Aspects described herein seek to reduce noise arising in a MEMS transducer package. Further, aspects seek to provide a lid structure which is designed to alleviate the problem of acoustic noise that arises as a result of interaction between air molecules moving with respect to one or more surfaces of the lid structure.

According to a first aspect there is provided a lid for a transducer package, wherein at least one interior surface of the lid is provided with a plurality of dimples.

A lid can be considered to be a single, substantially planar, layer or body of material which is spaced from the substrate of a transducer package so as to at least partially define an inner chamber of the package. It will be appreciated that the planar body may be formed of one or multiple layers of material e.g. a plated metal lid. Thus references to a “layer” herein should be interpreted as encompassing a laminated or multi-layer structure. Alternatively the lid may comprise an upper planar body/layer of material and one or more side walls which extend substantially orthogonally from the upper planar layer. Thus, the side walls of the package may be formed by the lid structure or by some other structure of the package/transducer.

The dimples serve to change the morphology of the inner surface of the lid. When arranged to form a lid of a MEMS microphone transducer, wherein air will flow in and out of the chamber via a sound port, the presence of the dimples gives rise to turbulent air flow at the interior surface of the lid in the vicinity of the dimples. This turbulence is caused by micro-vortices which develop in the open surface cavities. The generation of a turbulent layer of thus effectively creates a boundary between the interior surface of the lid and a moving stream of air within the chamber. Thus, the boundary layer advantageously serves to alleviate the occurrence of surface drag between the moving air and the interior surface of the lid, thereby reducing unwanted acoustic noise. The dimples can thus be considered to beneficially decouple the airflow from the lid surface.

### BRIEF DESCRIPTION OF DRAWINGS

For a better understanding of the present embodiments, and to show how the same may be carried into effect, reference will now be made, by way of example, to the accompanying drawings in which:

FIG. 1 illustrates a previous example of a “lid-type” package;

FIG. 2 illustrates a perspective view of a lid according to a first example;

FIG. 3 illustrates a cross sectional views of a lid for a transducer package according to second example;

FIG. 4 illustrates a cross sectional views of a lid for a transducer package according to third example; and

FIG. 5 provides a schematic illustration of a possible method for making a lid according to an example.

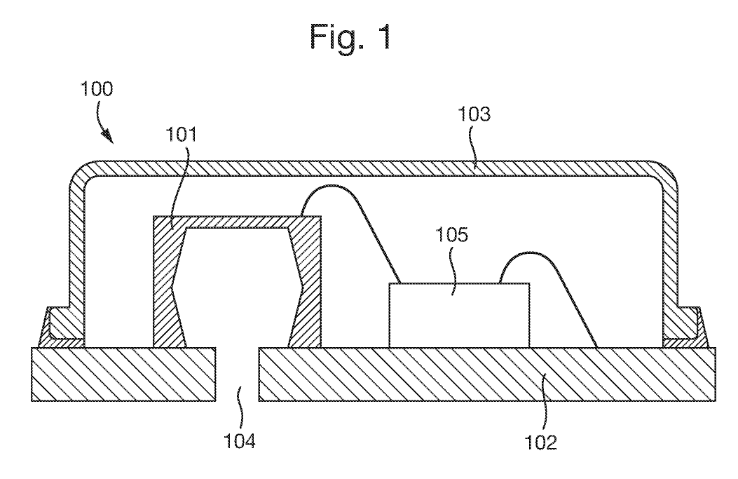

### DETAILED DESCRIPTION OF EMBODIMENTS

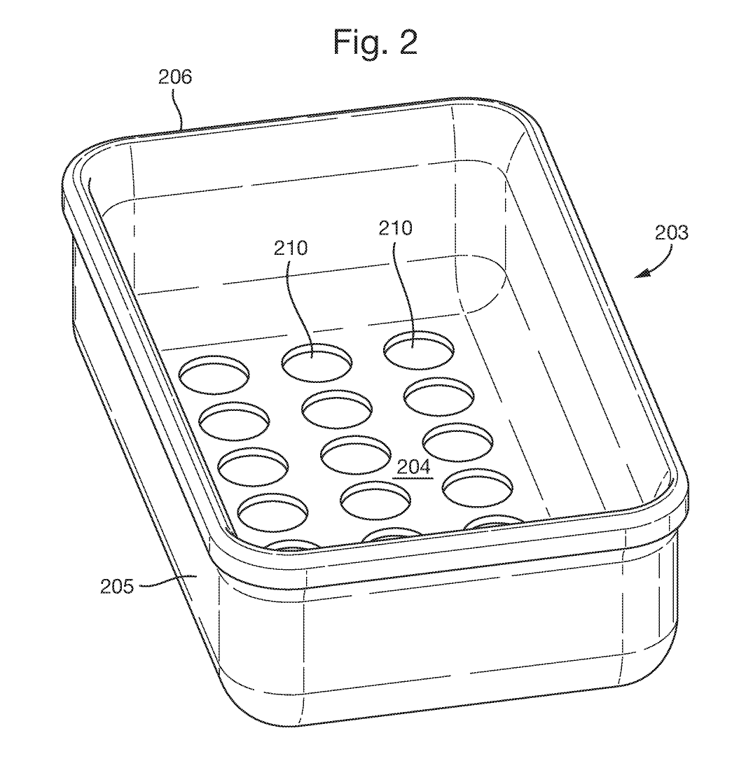

FIG. 2 shows a perspective view from below of a lid 203 according to a first example. The lid 203 comprises substantially planar surface 204 and a plurality of side walls 205 which extend from a foot 206 of the lid to the planar surface 204. An interior surface of the lid is provided with a plurality of dimples 210.

In this example the dimples 210 are provided on the interior surface of the planar surface 204 which can be considered to form a ceiling of the lid. However, in other examples, dimples may be additionally or alternatively provided on the inner surface of one or more of the side walls of the lid. In this example the dimples occupy a substantially circular area. However, other examples are envisaged in which the dimples may occupy an area of any shape, for example a substantially square or rectangular shape.

The dimples may preferably exhibit a width of between 100 μm and 300 μm, more preferably between 100 μm and 200 μm. The maximum depth of the dimples may preferably be between 5 and 25 microns.

The lid may be arranged in use to define, in conjunction with e.g. a substrate surface, an inner chamber of a package for a MEMS transducer.

It will be appreciated that the dimples serve to change the morphology of the inner surface of the lid. When arranged to form a lid of a MEMS microphone transducer, wherein air will flow in and out of the chamber via a sound port, the presence of the dimples gives rise to turbulent air flow at the interior surface of the lid in the vicinity of the dimples. This turbulence is caused by micro-vortices which develop in the open surface cavities. The generation of a turbulent layer of effectively creates a boundary between the interior surface of the lid and a moving stream of air within the chamber. Thus, the boundary layer advantageously serves to alleviate the occurrence of surface drag between the moving air and the interior surface of the lid, thereby reducing unwanted acoustic noise. The dimples can thus be considered to decouple the airflow from the lid surface.

A dimple can be considered to be a region where the thickness of the layer which forms the lid structure is reduced. Thus, one of more of the dimples may comprise a depressed region of material formed on an interior surface of the lid. In this respect, a dimple may be formed my impressing, stamping or otherwise compressing a region of the layer of material that will ultimately form an interior surface of the lid. Furthermore, one or more of the dimples may comprise a region where the material forming the lid structure is removed or ablated—e.g. by laser ablation.

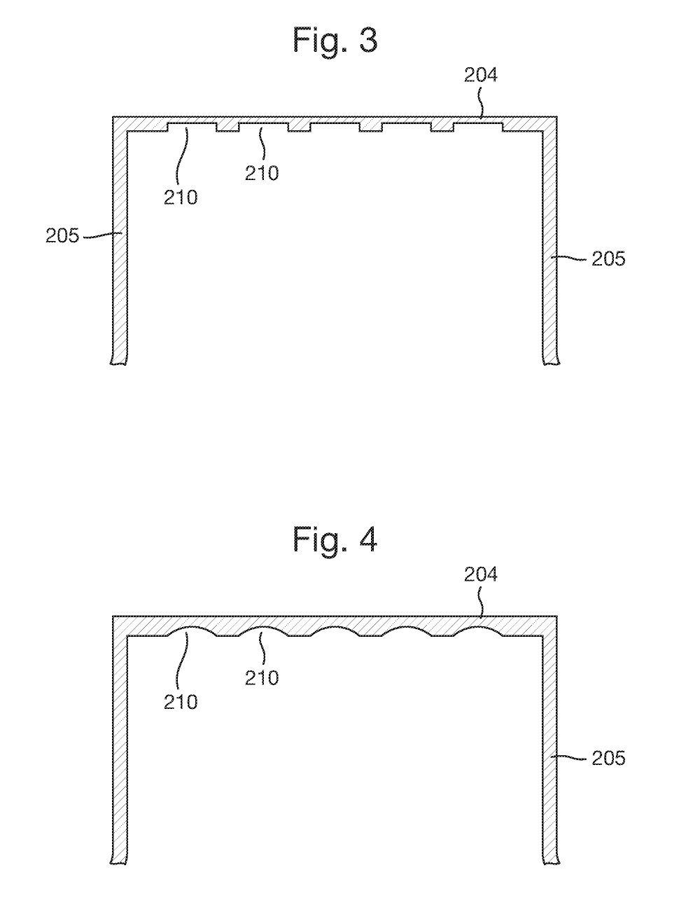

FIGS. 3 and 4 each illustrate a cross sectional views of a lid for a transducer package according to second and third examples respectively.

One or more of the dimples may exhibit a substantially uniform depth. Thus, as illustrated in FIG. 3, one or more dimples 210 may exhibit a disk or coin shape. Alternatively or additionally, one or more of the dimples may exhibit a non-uniform depth. Thus, as shown in FIG. 4, the surface of the dimple 210 may be substantially curved and/or one or more dimples may exhibit a substantially domed shape.

The dimples may be arranged in a regular or period pattern. Thus, the dimples may be arranged in a plurality of rows and/or columns with respect to the side edges of a given interior surface of the lid.

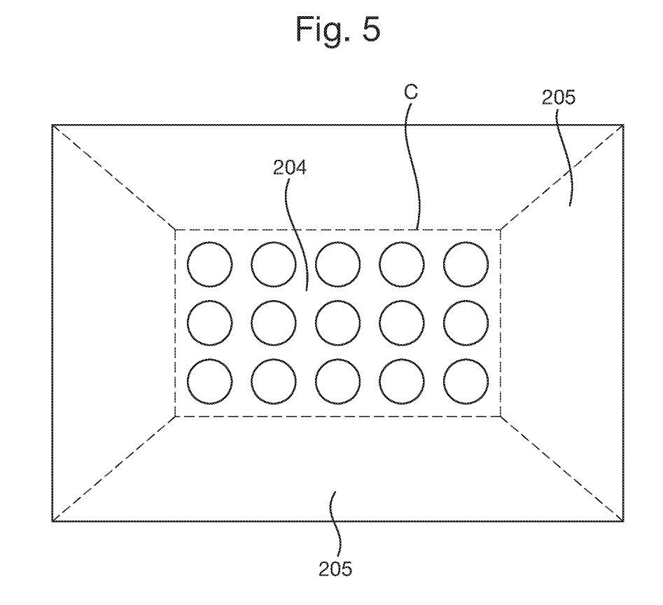

FIG. 5 provides a schematic illustration of a possible method for making a lid having a plurality of dimples provided in a ceiling surface of the lid. Specifically, a planar sheet of e.g. metal is provided. A plurality of dimples 210 are formed in a central region C of the planar sheet that will form an inner ceiling surface of the lid, by a process of impressing or stamping. The dimples may, for example, be substantially disk-shaped or substantially dome shaped. In a subsequent step (not illustrated) the planar sheet of metal is shaped or bent along the dotted to form a lid having an interior ceiling surface defined by the central region C and a plurality of sidewalls.

Thus, according to an embodiment of a further aspect, there is provided a method of forming a lid for a transducer package, the method comprising: forming a plurality of dimples in the surface of a planar sheet of metal;

bending the planar sheet of metal to define a lid having a planar surface which forms a ceiling of the lid and a plurality of side walls.

A package comprising a lid a described herein may comprise a MEMS transducer. The MEMS transducer may comprise a capacitive sensor, for example a microphone.

Although the various examples describe packaging for a MEMS capacitive microphone, the examples are also applicable to packaging for any form of MEMS transducers other than microphones, for example pressure sensors or ultrasonic transmitters/receivers. A transducer element may comprise, for example, a microphone device comprising one or more membranes with electrodes for read-out/drive deposited on the membranes and/or a substrate or back-plate. In the case of MEMS pressure sensors and microphones, the electrical output signal may be obtained by measuring a signal related to the capacitance between the electrodes. However, it is noted that the embodiments are also intended to embrace the output signal being derived by monitoring piezo-resistive or piezo-electric elements or indeed a light source.

It will be appreciated that a transducer may comprise other components, for example electrodes, or a backplate structure, wherein the flexible membrane layer is supported with respect to said backplate structure. The backplate structure may comprises a plurality of holes through the backplate structure.

The MEMS transducer may be formed on a transducer die and may in some instances be integrated with at least some electronics for operation of the transducer.

A MEMS transducer according to the examples described here may further comprise readout circuitry such as a low-noise amplifier, voltage reference and charge pump for providing higher-voltage bias, analogue-to-digital conversion or output digital interface or more complex analogue and/or digital processing or circuitry, or other components. There may thus be provided a package having an integrated circuit comprising a MEMS transducer as described in any of the examples herein.

A lid as described herein may be provided to form a package. The package may comprise one or more sound ports. A MEMS transducer may be located within a package together with a separate integrated circuit comprising readout circuitry which may comprise analogue and/or digital circuitry such as a low-noise amplifier, voltage reference and charge pump for providing higher-voltage bias, analogue-to-digital conversion or output digital interface or more complex analogue or digital signal processing for example a programmable digital signal processor.

An electronic device may be provided comprising a package having a lid according to any of the examples described herein. An electronic device may comprise, for example, at least one of: a portable device; a battery powered device; an audio device; a computing device; a communications device; a personal media player; a mobile telephone; a games device; and a voice controlled device.

It should be understood that the various relative terms upper, lower, top, bottom, underside, overlying, beneath, etc. that are used in the present description should not be in any way construed as limiting to any particular orientation of the lid or the package during any fabrication step and/or it orientation in any device or apparatus. Thus the relative terms shall be construed accordingly.

It should be noted that the above-mentioned examples illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. A lid for a transducer package, wherein an interior surface of the lid is provided with a plurality of dimples.

2. The lid as claimed in claim 1, wherein one of more of the dimples comprises a depressed region of material.

3. The lid as claimed in claim 1, wherein one or more of the dimples comprise a region where material has been removed.

4. The lid as claimed in claim 1, wherein one or more of the dimples exhibits a non-uniform depth.

5. The lid as claimed in claim 1, wherein one or more of the dimples exhibits a dome shape.

6. The lid as claimed in claim 1, wherein one or more of the dimples exhibits a substantially uniform depth.

7. The lid as claimed in claim 1, wherein one or more of the dimples exhibits a disk shape.

8. The lid as claimed in claim 1, wherein one or more of the dimples occupies a substantially circular area.

9. The lid as claimed in claim 1, wherein the dimples are provided in a ceiling surface of the lid.

10. The lid as claimed in claim 1, wherein the dimples are provided in a side-wall surface of the lid.

11. The lid as claimed in claim 1, wherein the dimples are arranged to form a regular array.

12. The lid as claimed in claim 1, wherein one or more of the dimples occupy a substantially square or rectangular area.

13. The lid as claimed in claim 1, wherein the lid is formed of metal.

14. A package for a MEMS transducer comprising a lid as claimed in claim 1, wherein the lid is mounted to a substrate to define a chamber of the package.

15. The package as claimed in claim 14, further comprising a MEMS transducer provided within the chamber.

16. The package as claimed in claim 15, said MEMS transducer comprising a flexible membrane and being provided such that the flexible membrane overlies a sound port provided with the substrate.

17. The package as claimed in claim 16, wherein the sound port couples to a first volume provided beneath the flexible membrane and wherein a second volume is defined on the other side of the flexible membrane.

18. The package as claimed in claim 15, wherein said MEMS transducer is a MEMS microphone.

19. The package as claimed in claim 14, further comprising an integrated circuit.

20. The package as claimed in claim 19, wherein the wherein said integrated circuit comprises analogue circuitry or digital circuitry.

21. The package as claimed in claim 20, wherein the integrated circuit comprises a programmable digital signal processor.

22. An electronic device comprising a package as claimed in claim 14, wherein said electronic device is at least one of: a portable device; a battery power device; a computing device; a communications device; a gaming device; a mobile telephone; an earphone or in-ear hearing aid, a personal media player; a laptop, tablet or notebook computing device.

23. A method of forming a lid for a transducer package, the method comprising:
forming a plurality of dimples in the surface of a planar sheet of metal; and
bending the planar sheet of metal to define a lid having a planar surface which forms a ceiling of the lid and a plurality of side walls.
